(19) United States
(12) Patent Application Publication
(10) Pub. No.: US 2009/0327832 A1
(43) Pub. Date: Dec. 31, 2009

(54) DECODER AND RECORDING/REPRODUCING DEVICE

(75) Inventor: Kazuhito Ichihara, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/410,176

(22) Filed: Mar. 24, 2009

(30) Foreign Application Priority Data
Jun. 30, 2008 (JP) 2008-170637

(51) Int. Cl. H03M 13/05; G06F 11/10

(52) U.S. Cl. 714/752; 714/E11.032

(57) ABSTRACT

A decoder and recording/reproducing device for preventing an increase in power consumption, has a multi-step iterative decoder. The decoder includes an iterative decoder in which a decoder constituted by a channel decoder and an outer code decoder is installed in multiple steps; an iterative decoding control circuit which estimates an error symbol count after decoding using likelihood information obtained from the outer decoder, stops the interactive decoding, if the estimated error symbol count exceeds an error symbols count, and corrects the residual errors that can be corrected by ECC using the ECC decoder. Therefore if a multi-step iterative decoder is used, the number of times of iterative decoding can be decreased and low power consumption can be implemented.

### CROSS-REFERENCE TO RELATED APPLICATIONS

This application is based upon and claims the benefit of priority of the prior Japanese Patent Application No. 2008-170637, filed on Jun. 30, 2008, the entire contents of which are incorporated herein by reference.

### FIELD

The present invention relates to a decoder and recording/reproducing device which decodes data, including error correction codes used for a recording/reproducing device and communication device, and more particularly to a decoder and recording/reproducing device for error correction in a data block in which ECC (Error Correction Code) is added.

### BACKGROUND

In the field of recording/reproducing devices, such as magnetic disk devices, and communication systems, error correction technology using error correction codes (ECC) is widely used to correct an error of data generated in the recording/reproducing process and in transmission paths.

For this ECC code, Reed Solomon (RS) code is used (e.g. Japanese Patent Application Laid-Open No. H11-330985). In the case of an RS code, RS encoding is preformed on recorded data in advance, and RS decoding is performed on a bit string reproduced via a recording/reproducing process, and an error included in the bit string is detected and corrected. In other words, the RS code excels in correction capability in symbol units, and in particular excels in detection and correction capability of a burst error.

As an error correction code technology, an iterative decoding method is used. Error detection and correction capability can be improved by combining iterative decoding and ECC. Recently a low density parity check (LDPC) codes, which is one iterative decoding method, have been developed for practical use.

In the case of LDPC code, LDPC encoding is performed on recorded data in advance, and iterative decoding based on a reliability propagation is performed on reproduced signals via the recording/reproducing process, whereby the error generated in the recording/reproducing process can be corrected (e.g. Japanese Patent Application Laid-Open No. 2007-166425).

Characteristic of LDPC encoding is that the code block length of linear codes is long, and the number of “1s” (check target bit) in the parity check matrix H is small (low density), and can be arranged at random.

In LDPC decoding, an error is corrected by performing decoding using reliability propagation which decodes by propagating likelihood (reliability to indicate the probability of data strings “0” and “1”), and iterative decoding (decoding performed iteratively between a partial response channel and reliability propagation decoder).

Now LDPC encoding and decoding are described. Since LDPC codes are linear codes, a parity check matrix H is generated so as to establish the following check conditions.

wH^{T}=0 (1)

In Expression (1), “w” indicates an LDPC-encoded code word, “H” indicates a parity check matrix, and “T” is a transposition.

When LDPC decoding is performed, the iterative decoding stops when a predetermined number of times of decoding is performed, or when the check conditions of Expression (1) are established, that is, when an error does not exist, and the result is output from the decoder.

Generally, as the likelihood, the Log-Likelihood Ratio (LLR), which is a logarithm of the ratio of probability to becomes “0” and probability to become “1”, is used. If the original binary data is “1”, a positive likelihood is given, and if “0”, a negative likelihood is given. Therefore when binarizing the decoded data string in iterative decoding output, a binary decision can be performed using a threshold decision unit of which threshold is “0”.

An encoder and decoder, which combine an RS code for ECC correction in symbol units with an LDPC code for error detection and correction in bit units in the pre-step of ECC using iterative decoding, have been proposed (e.g. Japanese Patent Application Laid-Open No. 2005-093038).

FIG. 10 is a block diagram depicting a signal processing system using conventional iterative decoding. An ECC encoder 100 adds ECC to write data at an encoder side (a write system in the case of a magnetic recording). An outer encoder 102 adds an LDPC code to the write data to which ECC is added.

This write data in which the outer code is added is sent to a magnetic recording/reproducing channel (head/medium) 110, and the head records this data onto a magnetic storage medium. In the magnetic recording/reproducing channel 110, the head reads this written data from the magnetic storage medium.

A decoder 120 for the magnetic recording/reproducing channel (head/medium) 110 performs binary (0, 1) decoding on read signals, and an ECC decoder 130 corrects errors that remain after decoding, using ECC (Error Correcting Code).

This decoder 120 is an iterative decoder comprised of a channel decoder (e.g. viterbi decoder, noise prediction decoder) 122 for the magnetic recording/reproducing channel and an outer code decoder 124 for outer codes (e.g. LDPC).

This iterative decoder demodulates the likelihood information from read signal using viterbi decoding, for example, and performs iterative decoding for a plurality of times using the likelihood information (probability value to be 0 or 1), then binary decision is performed by a binary (0, 1) decision unit 126, and errors that remain after the decoding are corrected by an ECC decoder 130 using ECC.

The channel decoder 122 and the outer code decoder 124 in this iterative decoding method require very complicated computing processing. Therefore if high-speed transfer is required, such as the case of a hard disk drive, designing circuits to construct channel decoders 122A to 122N and the outer decoders 124A to 124N to be a multi-step configuration has been proposed, as shown in FIG. 11 (e.g. Berrou et al, “Near Shannon Limit Error-Correcting Coding and Decoding: Turbo-Codes (1)”, IEEE Magnetic Recording Conference, 1993 (FIGS. 4a, 4b, 5).

Generally in the iterative decoding method, as shown in FIG. 12, it is known that the decoding capability increases as the number of times of iteration increases, and decoding capability (SNR: Signal to Noise Ratio, BER: Bit Error Rate) improves as the number of steps in the multiple step configuration increases.

In such recording/reproducing devices (magnetic recording/reproducing devices) and communication devices (e.g. portable telephones), demand to save energy is high. For example, a decrease in power consumption is highly demanded for a magnetic disk device, which is one magnetic recording/reproducing device, since a magnetic disk device is installed in a personal computer, portable equipment, car navigation equipment and the like.

If the above mentioned conventional multi-step iterative decoder is used for such a device, it is necessary to constantly operate a plurality of steps of the iterative decoder 120, which increases power consumption.

### SUMMARY

With the foregoing in view, it is an object of the present invention to provide a decoder and recording/reproducing device for preventing an increase in power consumption, even if a multi-step iterative decoder is used.

It is another object of the present invention to provide a decoder and recording/reproducing device for preventing an increase in power consumption and improving correcting capability and decoding speed, even if a multi-step iterative decoder is used.

It is still another object of the present invention to provide a decoder and recording/reproducing device for preventing an increase in power consumption and improving correction capability and decoding speed, even if a multi-step iterative decoder and ECC are combined.

To achieve the above-described objects, according to the present invention, a decoder for decoding a signal which is added an ECC code and an outer code to a predetermined number of bits, including: an iterative decoder in which a decoder constituted by a soft input soft output detector and an outer code decoder is installed in multiple steps; an ECC decoder which corrects a binary output of the iterative decoder using an ECC code; and an iterative decoding control circuit which estimates an error symbol count after decoding using likelihood information of the decoder and decides whether decoding is continued using a decoder in the next step of the iterative decoder based on the estimated error symbol count and an error symbol count which can be corrected by the ECC decoder, wherein when it is decided to continue the decoding, the iterative decoding control circuit outputs the likelihood information of a target decoder of the decision to a decoder in the next step and performs iterative decoding, and when it is decided not to continue the decoding, the iterative decoding control circuit outputs binary output of the likelihood information of the target decoder of the decision to the ECC decoder.

Also in the present invention, a recording/reproducing device for reading and decoding a signal which is added an ECC code and an outer code to a predetermined number of bits of data, from a storage medium, including: an iterative decoder to which the signal is input, and in which a decoder constituted by a soft input soft output detector and an outer code decoder is installed in multiple steps; an ECC decoder which corrects a binary output of the iterative decoder using an ECC code; and an iterative decoding control circuit which estimates an error symbol count after decoding using likelihood information of the decoder and decides whether decoding is continued using a decoder in the next step of the iterative decoder based on the estimated error symbol count and an error symbol count which can be corrected by the ECC decoder, wherein when it is decided to continue the decoding, the iterative decoding control circuit outputs the likelihood information of a target decoder of the decision to a decoder in the next step and performs iterative decoding, and when it is decided not to continue the decoding, the iterative decoding control circuit outputs binary output of the likelihood information of the target decoder of the decision to the ECC decoder.

Also in the present invention, it is preferable that the signal is a signal resulting after the data is interleaved, the ECC code is added to each interleaved data block, and de-interleave is then performed, and the iterative decoding control circuit interleaves the likelihood information of the decoder, estimates the error symbol count after decoding of each block using each likelihood information of the interleaved block, and decides whether decoding is continued using a decoder in the next step of the iterative decoder based on the estimated error symbol count of each block and error symbol count that can be corrected by the ECC decoder.

Also in the present invention, it is preferable that the iterative decoding control circuit estimates the error symbol count after decoding based on the likelihood information of the data and ECC code.

Also in the present invention, it is preferable that the iterative decoding control circuit detects the error by comparing a likelihood value of the likelihood information and a predetermined threshold, accumulates the detected error count, and estimates the error symbol count after decoding.

Also in the present invention, it is preferable that the iterative decoding control circuit judges whether the estimated error symbol count exceeds an error symbol count that can be corrected by the ECC decoder, and decides to continue the iterative decoding when it is judged that the estimated error symbol count exceeds the error symbol count that can be corrected by the ECC decoder.

Also in the present invention, it is preferable that the iterative decoding control circuit includes: a buffer which stores the likelihood information of the decoder; an error decision circuit which estimates the error symbol count after decoding using the likelihood information of the buffer, and decides whether decoding is continued by a decoder in the next step of the iterative decoder based on the estimated error symbol count and an error symbol count that can be corrected by the ECC decoder; a binary circuit which binarizes the likelihood information in the buffer; a first gate circuit which outputs the likelihood information in the buffer to the decoder in the next step of the iterative decoder when the error decision circuit decides to continue decoding; and a second gate circuit which outputs the likelihood information in the buffer to the binary circuit when the error decision circuit decides to continue decoding.

Also in the present invention, it is preferable that the iterative decoding control circuit compares the estimated error symbol count of each block and the error symbol count that can be corrected by the ECC decoder, calculates a block count that cannot be corrected, and decides whether decoding by the decoder in the next step of the iterative decoder is continued based on the block count that cannot be corrected.

Also in the present invention, it is preferable that the iterative decoding control circuit judges whether the estimated error symbol count in each block exceeds the error symbol count that can be corrected by the ECC decoder, and if exceeded, the iterative decoding control circuit judges the block as a block that cannot be corrected.

Also in the present invention, it is preferable that the outer code decoder comprises a low density parity decoder.

The error decision circuit estimates the error symbol count after decoding using likelihood information obtained from an iterative decoder in which an outer code decoder constituted, stops the interactive decoding, if the estimated error symbol count exceeds an error symbols count, and corrects the residual errors that can be corrected by ECC using the ECC decoder. Therefore when a multi-step iterative decoder is used, the number of times of iterative decoding can be decreased and low power consumption can be implemented.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram depicting a first embodiment of a decoder of the present invention;

FIG. 2 is a diagram depicting a configuration of an error decision unit in FIG. 1;

FIG. 3 is a diagram depicting the likelihood information of FIG. 1 and FIG. 2;

FIG. 4 is a diagram depicting the error decision operation in FIG. 2;

FIG. 5 is a diagram depicting a interleave operation of a second embodiment of the decoder of the present invention;

FIG. 6 is a diagram depicting a de-interleave operation of a second embodiment of the decoder of the present invention;

FIG. 7 is a block diagram depicting the second embodiment of a decoder of the present invention;

FIG. 8 is a flow chart depicting the iterative decoding control processing of the decoder according to the second embodiment of the present invention;

FIG. 9 is a flow chart depicting the iterative decoding control processing of the decoder according to the third embodiment of the present invention;

FIG. 10 is a block diagram depicting a signal processing system using conventional iterative decoding;

FIG. 11 is a block diagram of the signal processing using the conventional iterative decoding; and

FIG. 12 is a graph depicting the iterative decoding operation of FIG. 11.

### DESCRIPTION OF EMBODIMENTS

Embodiments of the present invention will now be described in the sequence of a first embodiment of a decoder, second embodiment of a decoder, third embodiment of a decoder and other embodiments, but the present invention is not limited to these embodiments.

### First Embodiment of a Decoder

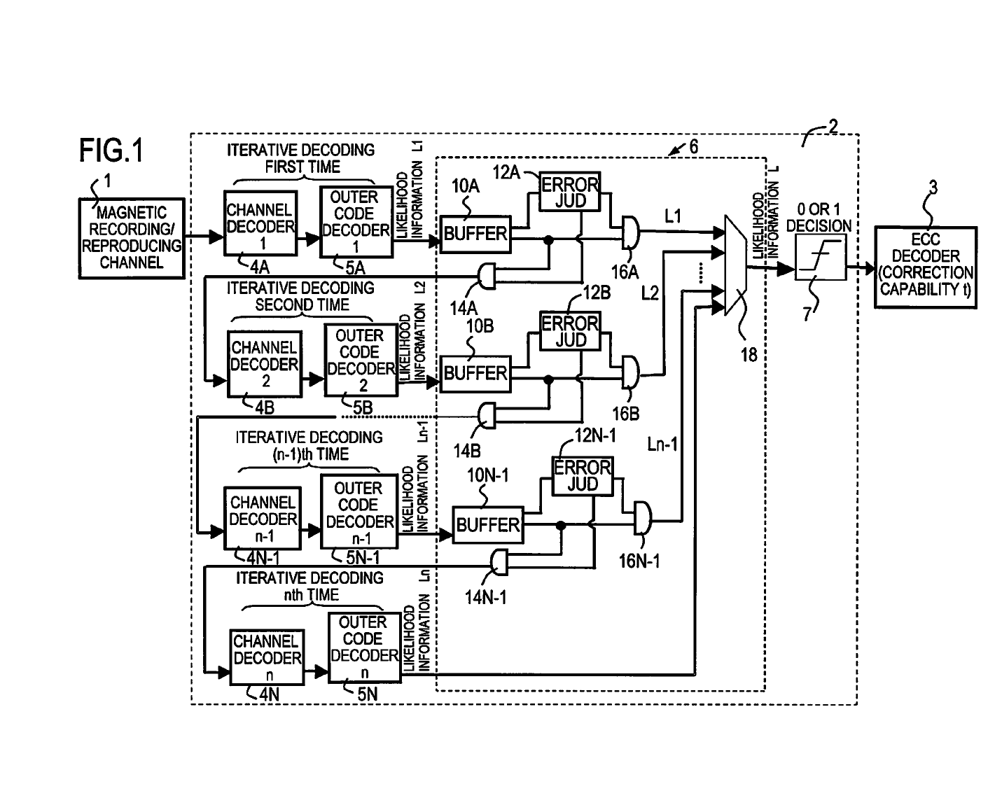

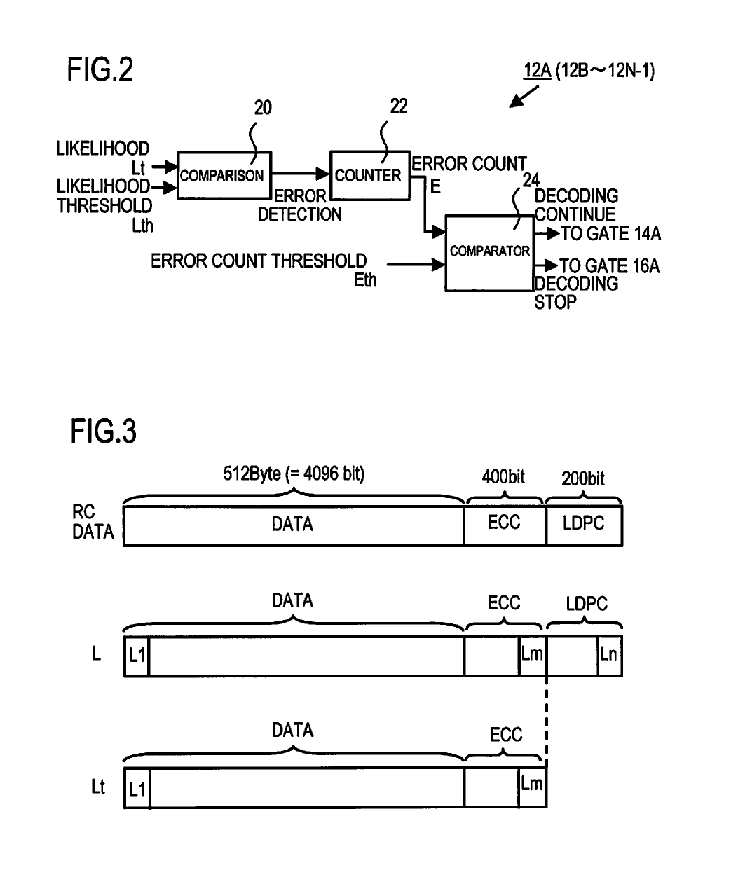

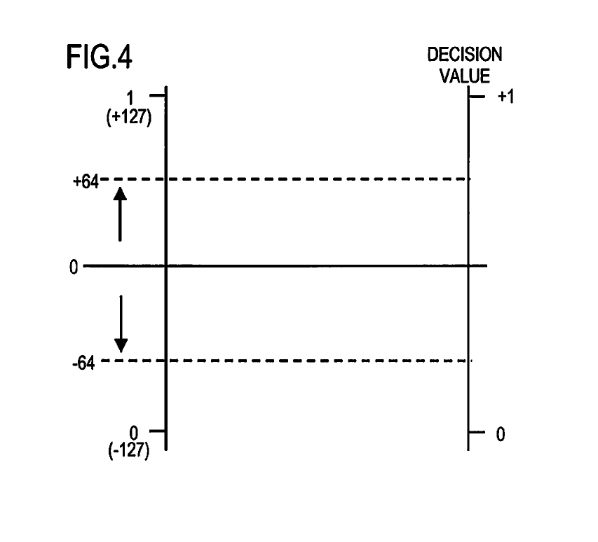

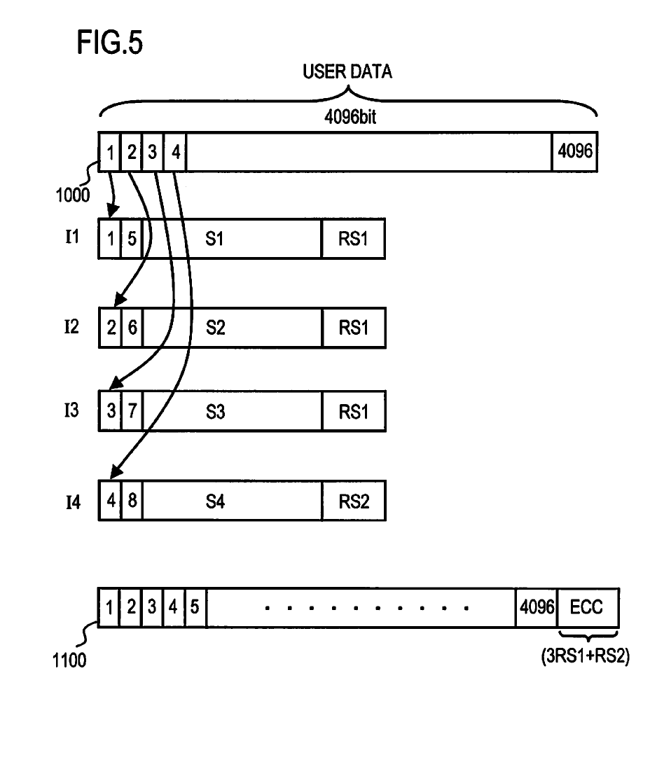

FIG. 1 is a block diagram depicting a first embodiment of a decoder of the present invention, FIG. 2 is a diagram depicting a configuration of an error decision unit in FIG. 1, FIG. 3 is a diagram depicting the operation of FIG. 1 and FIG. 2, and FIG. 4 is a diagram depicting the error decision operation in FIG. 2. FIG. 1 shows a recording/reproducing system of the magnetic disk device.

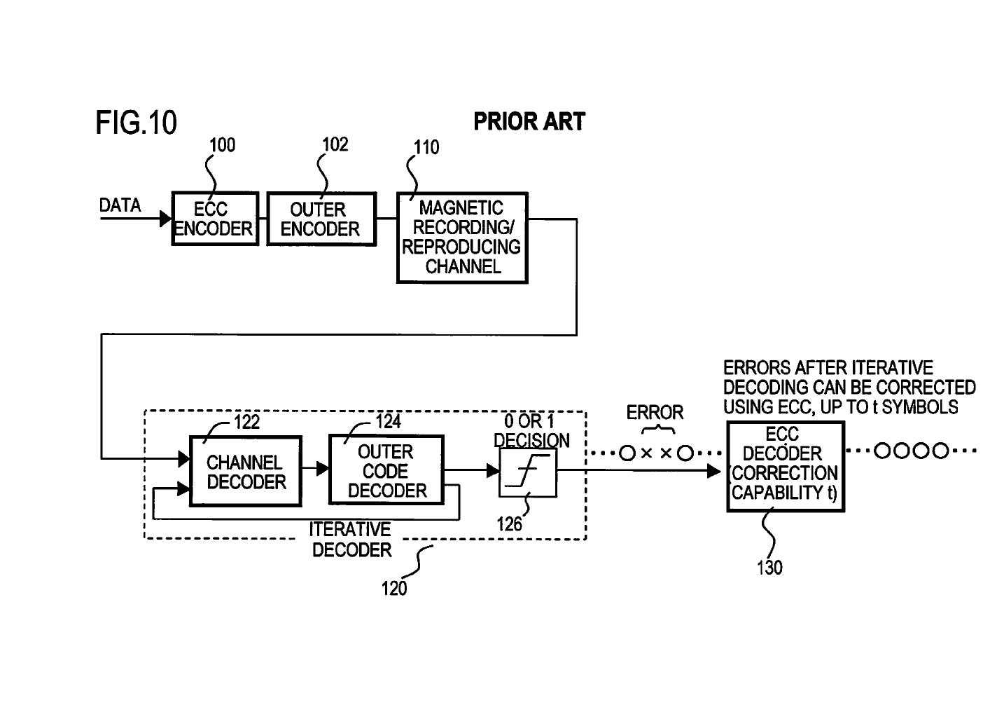

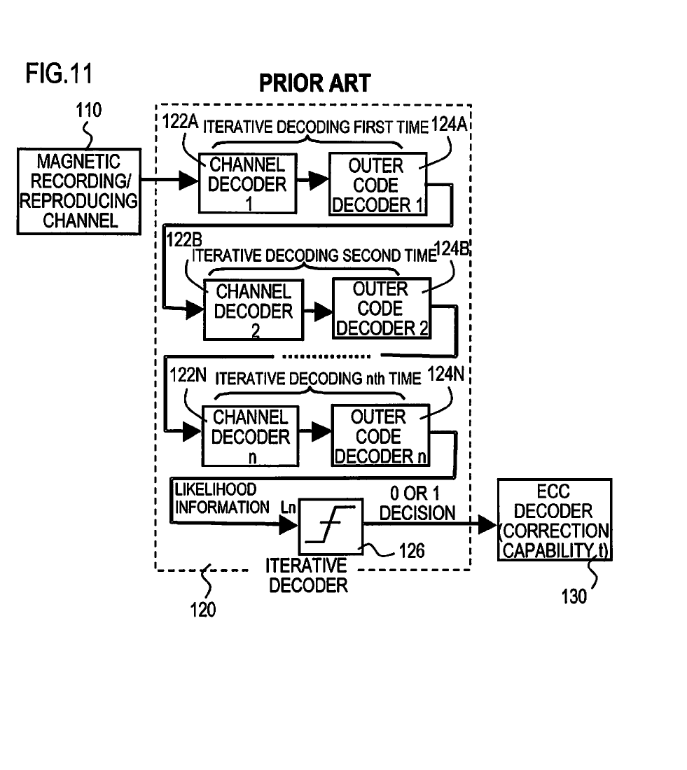

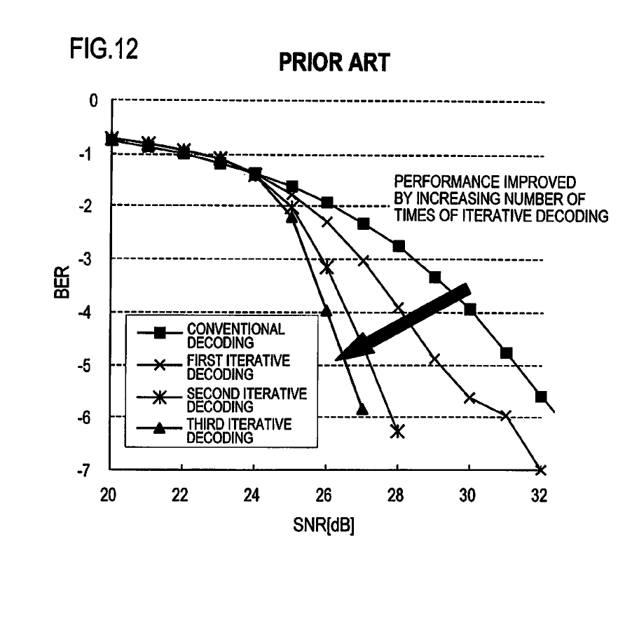

As FIG. 1 indicates, a magnetic recording/reproducing channel 1 is comprised of a magnetic head and a magnetic disk. Encoding data described in FIG. 10 is recorded on the magnetic disk by a magnetic head.

When recording (encoding), for example, CRC (Cyclic Redundancy Code) is added to the recorded data by a CRC encoder, and then the recorded data is converted into a data string by a recording encoder, so as to satisfy such constraints as MTR (Maximum Transition Run) code and RLL (Run Length Limited) code. Then the ECC encoder 100 in FIG. 10 adds the ECC (Error Correction Code). For the ECC-encoded data string, an LDPC encoder 102 determines an LDPC parity for detecting an error separate from the ECC, for each LDPC block, and adds each LDPC parity to the parity-encoded ECC-encoded data string to each LDPC block as shown in FIG. 3.

A recording compensator performs a compensation processing to increase a reversal spacing slightly at a location where the reversal of magnetization is immediately next to each other, and a driver generates a write current of a magnetic head (write head), which is not illustrated, drives the recording head, and records the data string, of which recording was compensated, on a magnetic disk, which is not illustrated, via a preamplifier.

Therefore the recorded data string RCDATA has a format in which ECC and LDPC are added to the recording data DATA, as indicated by FIG. 3. For example, when the recorded data is 512 bytes (=4096 bits), 400 bits of ECC and 200 bits of LDPC are added. In this example, the correction capability ‘t’ of ECC is 200 bits.

In the magnetic recording/reproducing channel 1, PR (Partial Response) waveform equalization is performed on the signal of the data string which the magnetic head read from the magnetic disk, via a preamplifier, a variable gain amplifier (VGA), a low pass filter (LPF) and FIR (Finite Impulse Response) filter, which are not illustrated, and then this signal is input to the iterative decoder 2.

The iterative decoder 2 is comprised of channel decoders 4A to 4N (soft input soft output detectors) and outer code decoders (LDPC decoders) 5A to 5N, and performs iterative decoding using likelihood. The soft input soft output detectors 4A to 4N use a Max-log-MAP (Maximum A Posteriori) algorithm, SOVA (Soft-Output Viterbi Algorithm), and noise predictive SOVA (NPSOVA), for example. The LDPC decoders 5A to 5N use a Sum-Product algorithm and Min-Sum algorithm, for example.

N pairs (N steps) of channel decoders 4A to 4N (soft input soft output detectors) and outer code decoder (LDPC decoders) 5A to 5N are installed, and each output (likelihood) is input to an iterative decoding control circuit 6.

The iterative decoding control circuit 6 decides whether an error count in one iterative decoding result is within the ECC correction capability, and decides that continuation of iterative decoding is unnecessary if the error count is within the ECC correction capability, and instructs continuation of the iterative decoding if the error count is not within the ECC correction capability (exceeds the ECC correction capability).

In other words, the iterative decoding control circuit 6 has a first buffer 10A which temporarily stores the likelihood information of the outer code decoder 5A for the iterative decoders (channel decoder 4A and outer code decoder 5A) in the first step, an error decision unit 12A which compares the likelihood information of the first buffer 10A and a predetermined threshold, judges whether errors exist and decides whether decoding is to continue, a first gate circuit 16A which outputs the likelihood information L of the first buffer 10A to an OR circuit 18 if the error decision unit 12A decides that continuation of decoding is unnecessary, and a second gate circuit 14A which outputs the likelihood information L of the first buffer 10A to the channel decoder 4B in the next step if the error decision unit 12A decides that continuation of decoding is necessary.

In the same manner, the iterative decoding control circuit 6 has a second buffer 10B which temporarily stores the likelihood information of the outer code decoder 5B for the iterative decoders (channel decoder 4B and outer code decoder 5B) in the second step, an error decision unit 12B which compares the likelihood information of the second buffer 10B and a predetermined threshold, judges whether errors exist and decodes whether decoding is to continue, a first gate circuit 16B which outputs the likelihood information L of the second buffer 10B to the OR circuit 18 if the error decision unit 12B decides that continuation of decoding is unnecessary, and a second gate circuit 14B which outputs the likelihood information L of the second buffer 10B to the channel decoder 4C in the next step if the error decision unit 12B decides that continuation of decoding is necessary.

In the same manner, the iterative decoding control circuit 6 has a (N−1)th buffer 10N−1 which temporarily stores the likelihood information of the outer code decoder 5N−1 for the iterative decoders (channel decoder 4N−1 and outer code decoder 5N−1) in the (N−1)th step, an error decision unit 12N−1 which compares the likelihood information of the (N−1)th buffer 10N−1 and a predetermined threshold, judges whether errors exist and decides whether decoding is to continue, and a first gate circuit 16N−1 which outputs the likelihood information L of the (N−1)th buffer 10N−1 to the OR circuit 18 if the error decision unit 12N−1 decides that continuation of decoding is unnecessary, and a second gate circuit 14N−1 which outputs the likelihood information L of the (N−1)th buffer 10N−1 to the channel decoder 4N in the last step if the error decision unit 12N−1 decides that continuation of decoding is necessary.

The OR gate circuit 18 determines the OR of the output of each gate circuit 16A to 16N−1 and the outer code decoder 5N in the last step, and outputs the value to the binary circuit 7. The binary circuit 7 converts the likelihood information into a hard decision value (1 or 0) using a predetermined threshold, and outputs the value to an ECC decoder 3.

The iterative decoding control circuit 6 will now be described with reference to FIG. 2 to FIG. 4. As FIG. 3 indicates, the outer code decoders 5A to 5N create the likelihood information L for each bit of data DATA, ECC and LDPC. The likelihood information L is comprised of 8-bit likelihood values, if the hard decision value “1” is “+127” and the hard decision value “0” is “−127”, for example, as indicated by FIG. 4.

Here the binary circuit 7 is normally the value “0”, and outputs a hard decision value “1” or “0”. In this likelihood value, the likelihood of the bit is higher as the absolute value of the likelihood value is higher. In the case of the example in FIG. 4, when the hard decision value is “1”, the likelihood is higher as the likelihood value is closer to “+127”, and when the hard decision value is “0”, the likelihood is higher as the likelihood value is closer to “−127”. Therefore the probability of error is high when the likelihood is between “+64” and “−64”, for example.

Hence for error decision, the case when the likelihood value is “+64” to “−64” is judged as an error. As FIG. 3 indicates, the target likelihood value Lt of the error decision is based on a likelihood value L of the data DATA and ECC here, and the likelihood value of LDPC, which is used for iterative decoding and is not used for ECC decoding, is omitted here.

As FIG. 2 indicates, the likelihood value Lt of the data DATA and ECC of the buffer 10A (10B to 10N−1) is compared with the likelihood threshold Lth by the first comparator 20. In the case of the example in FIG. 4, the likelihood threshold Lth is “64” and “−64”, and the first comparator 20 outputs an error detection signal to the counter 22 when the likelihood value input is “+64” to “−64”.

The counter 22 counts the error detection signals and accumulates the error count. The second comparator 24 compares the error count of the counter 22 and the error count threshold Eth when error detection, based on all the likelihood values of the data DATA and ECC, ends. This error count threshold Eth is a correction capability ‘t’ (symbols) of the ECC decoder 3, and is “200” in the case of the example in FIG. 3.

If it is judged that the error count of the counter 22 exceeds the error count threshold Eth, the second comparator 24 decides to continue the iterative decoding since the error count exceeds the correction capability of the ECC decoder 3, and outputs the likelihood value L (including LDPC) in FIG. 3 of the buffer 10A (10B to 10N−1) from the second gate circuit 14A (14B to 14N−1) to the channel decoder 4B (4C to 4N) in the next step.

If it is judged that the error count of the counter 22 does not exceed the error count threshold Eth, the second comparator 24 decides to stop the iterative decoding since the error count does not exceed the correction capability of the ECC decoder 3, and outputs the likelihood value L (excluding LDPC) in FIG. 3 of the buffer 10A (10B to 10N−1) from the first gate circuit 16A (16B to 16N−1) to the OR gate circuit 3. The likelihood value of the data DATA and ECC from the OR gate circuit 3 is binarized by the binary circuit 7, and is output to the ECC decoder 3.

In this way, the error symbol count after decoding is estimated by the error decision unit 12A (12B to 12N−1) using the likelihood information L from the outer code decoder 5A (5B to 5N−1) constituting the iterative decoder, and iterative decoding is stopped if the error symbol count is correctable by ECC, and the residual errors that can be corrected by ECC are corrected using the ECC decoder 3.

Therefore if a multi-step iterative decoder is used, the number of times of iterative decoding can be decreased and low power consumption can be implemented. In other words, power is input to each iterative decoder in each step, and iterative decoding operation is executed when a signal is input, so if a signal is not input, operation is not performed even if power is ON, and as a result, power consumption can be decreased.

### Second Embodiment of a Decoder

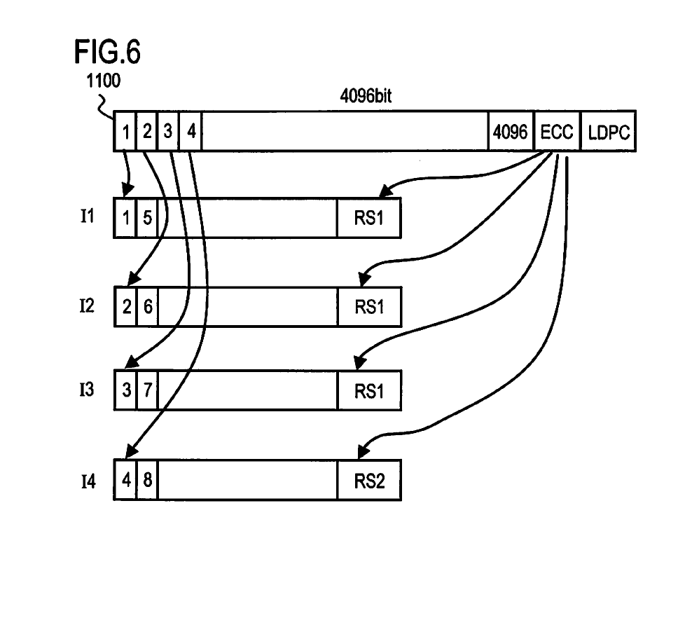

FIG. 5 and FIG. 6 are diagrams depicting a second embodiment of the iterative decoding method of the present invention. This embodiment is an example when the present invention is applied to Integrated Interleaving ECC (IIECC), which is an iterative decoding method which implements even lower power consumption. IIECC, which is explained by M. Hassner in IEEE Trans. On Mag., Vol. 37, No. 2 (March 2001), will be described in brief.

A two-level IIECC has two types of correction capability: ta and tb (ta<tb). In other words, in IIECC, two IIECC parity codes, RS (Reed Solomon) codes RS1 and RS2, having different error correction counts, are provided. The correction count of RS1 is ta, and the correction count of RS2 is tb (>ta).

The generating polynomials of RS1 and RS2 are given by the following Expressions (2) and (3).

RS1=(x−α)·(x−α²) . . . (x−α^{2t1}) (2)

RS2=(x−α)·(x−α²) . . . (x−α^{2t2}) (3)

FIG. 5 shows an example of four-interleave IIECC. As FIG. 5 indicates, when encoding, the recorded data 1000 (4096 bits in this case) is interleaved into 4. In each interleaved block I1 (S1), I2 (S2), I3 (S3) and I4 (S4), a bit in every 4 bits in the recorded data 1000 is sequentially disposed. The 3 blocks I1, I2 and I3 are encoded using RS1. The blocks I1, I2, I3 and I4 are added, and are encoded using RS2.

Then de-interleave is performed to create the RS encoded string 1100. The RS encoded string 1100 is the recorded data 1000 to which ECC, comprised of RS1 and RS2, is added. LDPC is added to this RS encoded string 1100, just like FIG. 3.

As FIG. 6 indicates, when decoding is performed as well, the RS encoded string 1100 is interleaved into 4 blocks: I1, I2, I3 and I4, and ECC correction is performed using the parity strings RS1 and RS2.

In IIECC, errors up to ta symbols can be corrected per one interleave, and errors up to tb symbols can be corrected in one interleave block, out of all the interleave blocks I1 to I4.

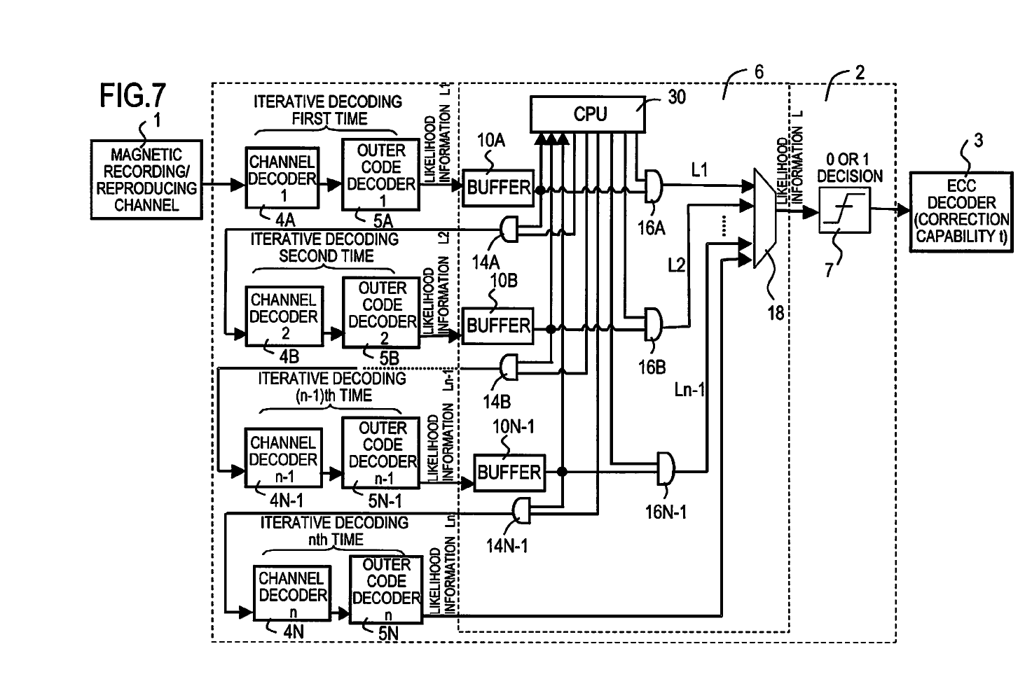

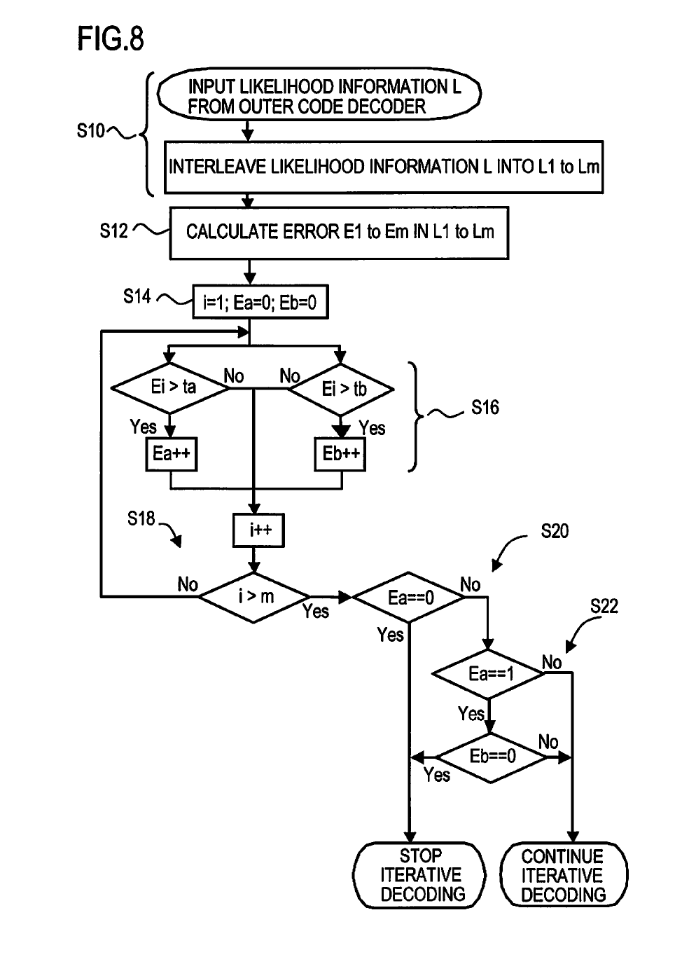

Next an embodiment using IIECC will be described. FIG. 7 is a block diagram depicting the second embodiment of a decoder of the present invention, and FIG. 8 is a flow chart depicting the iterative decoding control processing in FIG. 7. In FIG. 7, composing elements the same as FIG. 1 are denoted with the same symbols.

Just like FIG. 1, a read signal from a magnetic recording/reproducing channel 1 is input to an iterative decoder 2. The iterative decoder 2 is comprised of channel decoders 4A to 4N (soft input soft output detectors) and outer code decoders (LDPC decoders) 5A to 5N, and performs iterative decoding using likelihood. The soft input soft output detectors 4A to 4N use Max-log-MAP (Maximum A Posteriori) algorithm, SOVA (Soft-Output Viberbi Algorithm) and noise predictive SOVA (NPSOVA), for example. The LDPC decoders 5A to 5N use Sum-Product algorithm and Min-Sum algorithm, for example.

N pairs (N steps) of the channel decoders 4A to 4N (soft input soft output detectors) and outer code decoders (LDPC decoders) 5A to 5N are installed, and each output (likelihood) is input to an iterative decoding control circuit 6.

The iterative decoding control circuit 6 decides whether an error count in one iterative decoding result is within the ECC correction capabilities ta and tb, and decides whether continuation of iterative decoding is unnecessary if the error count is within the ECC correction capability, and instructs continuation of the iterative decoding if the error count is not within the ECC error capability (exceeds the ECC correction capability).

In other words, the iterative decoding control circuit 6 has a first buffer 10A which temporarily stores the likelihood information of the outer code decoder 5A for the iterative decoders (channel decoder 4A and outer code decoder 5A) in the first step, a first gate circuit 16A which outputs the likelihood information L of the first buffer 10A to an OR circuit 18 if a later mentioned CPU 30 decides that continuation of decoding is unnecessary, and a second gate circuit 14A which outputs the likelihood information L of the first buffer 10A to the channel decoder 4B on the next step if the CPU 30 decides that continuation of decoding is necessary.

In the same manner, the iterative decoding control circuit 6 has a second buffer 10B which temporarily stores the likelihood information of the outer code decoder 5B for the iterative decoders (channel decoder 4B and outer code decoder 5B) in the second step, a first gate circuit 16B which outputs the likelihood information L of the second buffer 10B to the OR circuit 18 if the CPU 30 decides that continuation of decoding is unnecessary, and a second gate circuit 14B which outputs the likelihood information L of the second buffer 10B to the channel decoder 4C in the next step if the CPU 30 decides that continuation of decoding is necessary.

In the same manner, the iterative decoding control circuit 6 has a (N−1)th buffer 10N−1 which temporarily stores the likelihood information of the outer code decoder 5N−1 for the iterative decoders (channel decoder 4N−1 and outer code decoder 5N−1) in the (N−1)th step, a first gate circuit 16N−1 which outputs the likelihood information L of the (N−1)th buffer 10N−1 to the OR circuit 18 if the CPU 30 decides that continuation of decoding is unnecessary, and a second gate circuit 14N−1 which outputs the likelihood information L of the (N−1)th buffer 10N−1 to the channel decoder 4N in the last step, if the CPU 30 decides that continuation of decoding is necessary.

The OR gate circuit 18 determines the OR of the output of each gate circuit 16A to 16N−1 and the outer code decoder 5N in the last step, and outputs the value to a binary circuit 7. The binary circuit 7 converts the likelihood information into a hard decision value (1 or 0) using a predetermined threshold, and outputs the value to an ECC decoder 3.

A CPU (error decision unit) 30 estimates an error symbol count based on the likelihood information (likelihood value) of each buffer in the processing in FIG. 8, and stops the iterative decoding if the conditions to correct by IIECC (ta, tb) are satisfied, and corrects residual correctable errors using IIECC3.

By using FIG. 8, decoding process is described. (S10) The CPU 30 receives the likelihood information L of the data DATA and ECC described in FIG. 3 from the buffer 10A (10B to 10N−1), and interleaves the likelihood information L into m (4 in FIG. 6), just like the case of FIG. 6.

(S12) The CPU 30 calculates the error count E1 to Em in each interleave block L1 to Lm (L1 to L4 in FIG. 6). For this calculation, the likelihood value Lt is compared with the likelihood threshold Lth, just like the case of FIG. 2, errors are detected based on this comparison result, error detection signals are counted by a counter, and the error count is accumulated.

(S14) Then in order to judge whether an error count of each interleave block satisfies the correctible conditions, the CPU 30 initializes an interleave pointer i to “0”, and the condition pointers Ea and Eb to “0”.

(S16) The CPU 30 judges whether the error count Ei of the i-th interleave exceeds the correctable symbol count ta. The CPU 30 increments the condition pointer Ea by “1” if the error count Ei exceeds the correctable symbol count ta. In the same manner, the CPU 30 judges whether the error count Ei of the i-th interleave block exceeds the correctable symbol count tb. The CPU 30 increments the condition pointer Eb by “1” if the error count Ei exceeds the correctable symbol count tb.

(S18) The CPU 30 increments the interleave pointer i by “1”. Then the CPU 30 judges whether the interleave pointer i exceeds the interleave count m. If the CPU 30 judges that the interleave pointer i does not exceed the interleave count m, the processing returns to step S16.

(S20) If the CPU 30 judges that the interleave pointer i exceeds the interleave count m, the check of error count of all interleave blocks ends. Therefore the CPU 30 judges whether the condition pointer Ea is “0”. If the condition pointer Ea is “0”, the CPU 30 instructs to stop the iterative decoding.

If the condition pointer Ea is not “0”, the CPU 30 judges whether the condition pointer Ea is “1”. If the condition pointer Ea is not “1”, it means that correction is impossible by IIECC, so the CPU 30 instructs to continue the iterative decoding. If the condition pointer Ea is “1”, the CPU 30 judges whether the condition pointer Eb is “0”. If the condition pointer Eb is “0”, it means that correction is possible by IIECC, so the CPU 30 instructs to stop the iterative decoding. If the condition pointer Eb is not “0”, it means that correction is impossible by IIECC, so the CPU 30 instructs to continue the iterative decoding.

Just like FIG. 1, in the case of continuing the iterative decoding, the likelihood L (including LDPC) of the buffer 10A (10B to 10N−1) is output from the second gate circuit 14A (14B to 14N−1) to the channel decoder 4B (4C to 4N) in the next step.

If it is judged to stop the iterative decoding, the likelihood L (excluding LDPC) of the buffer 10A (10B to 10N−1) is output from the first gate circuit 16A (16B to 16N−1) to the OR gate circuit 3. The likelihood values of the data DATA and ECC from the OR gate circuit 3 are binarized by the binary circuit 7, and are output to the ECC decoder 3.

In this way, the error symbol count after decoding is estimated by the error decision unit 30 using the likelihood information L from the outer code decoder, and the iterative decoding is stopped if the conditions to correct using IIECC (ta, tb) are satisfied, and correctable residual errors are corrected using IIECC. Therefore stopping iterative decoding can be decided quicker than when using ECC, and the number of times of iterative decoding can be decreased, and low power consumption can be implemented.

### Third Embodiment of a Decoder

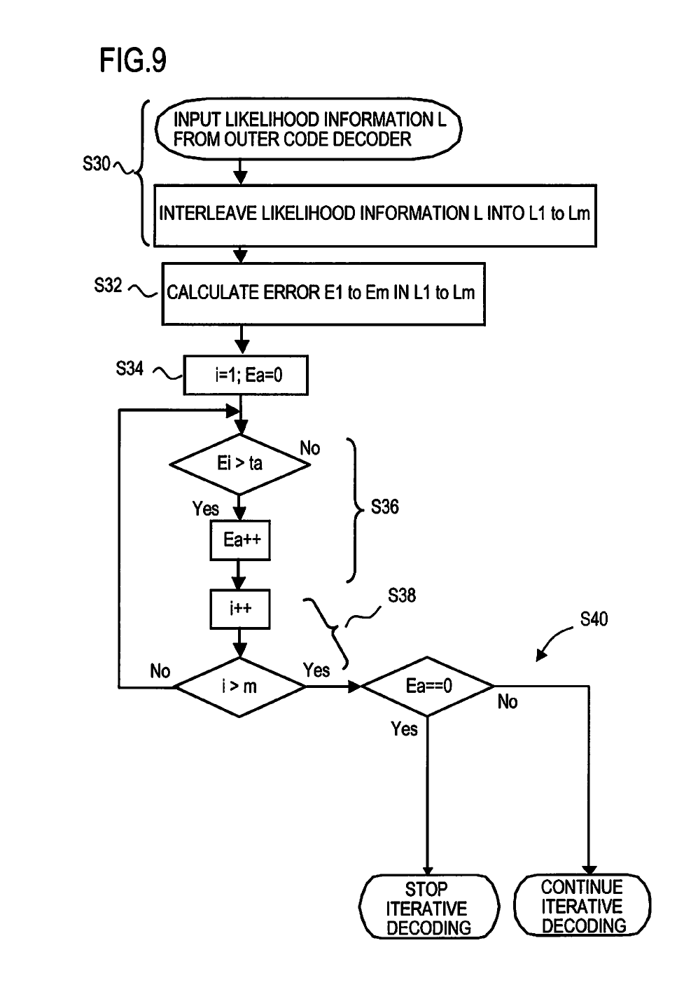

FIG. 9 is a flow chart depicting an iterative decoding control processing according to a third embodiment of the decoder of the present invention.

This embodiment uses only ta, which is a correction capability per one interleave in IIECC, as a condition to stop iterative decoding in the configuration in FIG. 7. Therefore the processing of the CPU 30 in FIG. 7 is described with reference to FIG. 9.

(S30) The CPU 30 receives the likelihood information L of the data DATA and ECC described in FIG. 3 from the buffer 10A (10B to 10N−1), and interleaves the likelihood information L into m (4 in FIG. 6), just like the case of FIG. 6.

(S32) The CPU 30 calculates the error count E1 to Em in each interleave block L1 to Lm (L1 to L4 in FIG. 6). For this calculation, the likelihood value Lt is compared with the likelihood threshold Lth, just like the case of FIG. 2, errors are detected based on this comparison result, error detection signals are counted by a counter, and the error count is accumulated.

(S34) Then in order to judge whether the error count in each interleave block satisfies the correctable condition, the CPU 30 initializes the interleave pointer i to “0”, and the condition pointer Ea to “0”.

(S36) The CPU 30 judges whether the error count Ei of the i-th interleave block exceeds the correctable symbol count ta. If the error count Ei exceeds the correctable symbol count ta, the CPU 30 increments the condition pointer Ea by “1”.

(S38) The CPU 30 increments the interleave pointer i by “1”. Then the CPU 30 judges whether the interleave pointer i exceeds the interleave count m. If the CPU 30 judges that the interleave pointer i does not exceed the interleave count m, processing returns to step S36.

(S40) If the CPU 30 judges that the interleave pointer i exceeds the interleave count m, checking of error count of all interleave blocks ends. Therefore the CPU 30 judges whether the condition pointer Ea is “0”. If the condition pointer Ea is “0”, the CPU 30 instructs to stop the iterative decoding.

If the condition pointer Ea is not “0”, it means that correction is impossible by IIECC, so the CPU 30 instructs to continue iterative decoding.

Just like FIG. 1, if the iterative decoding is continued, the likelihood value L (including LDPC) of the buffer 10A (10B to 10N−1) is output from the second gate circuit 14A (14B to 14N−1) to the channel decoder 4B (4C to 4N) in the next step.

If it is judged to stop the iterative decoding, the likelihood value L (excluding LDPC) of the buffer 10A (10B to 10N−1) is output from the first gate circuit 16A (16B to 16N−1) to the OR gate circuit 3. The likelihood values of the data DATA and ECC from the OR gate circuit 3 are binarized by the binary circuit 7, and are output to the ECC decoder 3.

In this way, the error symbol count after decoding is estimated by the error decision unit 30 using the likelihood information L from the outer code decoder, and the iterative decoding is stopped if the error count in each interleave is within ta symbols, and correctable residual errors are corrected using IIECC.

In this embodiment, even if errors exceeding ta are generated in an interleave and the error decision unit 30 judged it as errors less than ta and stops the iterative decoding, these errors can be corrected using IIECC if the error count is tb or less, therefore even more stable operation is possible.

### Other Embodiments

In the above embodiments, Reed Solomon code was described as the ECC code, but other codes, such as BCH (Bose Chaudhari Hocquengham) code can also be used. The interleave configuration described above is four interleaves, but the present invention can be applied to a two or more interleave configuration. The described examples are the case of a recording/reproducing device of a magnetic disk device, but the present invention can also be applied to other media storage devices, such as an optical disk device, or to communication devices.

The present invention was described using the embodiments, but the present invention can be modified in various ways within the scope of the spirit thereof, and these variant forms shall not be excluded from the scope of the present invention.

The error decision circuit estimates the error symbol count after decoding using likelihood information obtained from an iterative decoder in which an outer code decoder constituted, judges whether the estimated error symbol count exceeds an error symbol count that can be corrected by the ECC decoder, stops the interactive decoding, if the estimated error symbol count exceeds an error symbols count, and corrects the residual errors that can be corrected by ECC using the ECC decoder. Therefore if a multi-step iterative decoder is used, the number of times of iterative decoding can be decreased and low power consumption can be implemented.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A decoder for decoding a signal which is added an ECC code and an outer code to a predetermined number of bits of data, comprising:
a iterative decoder comprising a plurality of decoder which is each constituted by a soft input soft output detector and an outer code decoder and is constructed in multiple steps;
an ECC decoder which corrects a binary output of the iterative decoder using an ECC code; and
an iterative decoding control circuit which estimates an error symbol count after decoding using likelihood information of the decoder and decides whether decoding is continued using a decoder in the next step of the iterative decoder based on the estimated error symbol count and an error symbol count which can be corrected by the ECC decoder,
wherein when it is decided to continue the decoding, the iterative decoding control circuit outputs the likelihood information of a target decoder of the decision to a decoder in the next step and performs iterative decoding, and when it is decided not to continue the decoding, the iterative decoding control circuit outputs binary output of the likelihood information of the target decoder of the decision to the ECC decoder.

2. The decoder according to claim 1, wherein the signal is a signal resulting after the data is interleaved, the ECC code is added to each interleaved data block, and de-interleave is then performed,
and the iterative decoding control circuit interleaves the likelihood information of the decoder, estimates the error symbol count after decoding of each block using each likelihood information of the interleaved block, and decides whether decoding is continued using a decoder in the next step of the iterative decoder based on the estimated error symbol count of each block and error symbol count that can be corrected by the ECC decoder.

3. The decoder according to claim 1, wherein the iterative decoding control circuit estimates the error symbol count after decoding based on the likelihood information of the data and ECC code.

4. The decoder according to claim 1, wherein the iterative decoding control circuit detects the error by comparing a likelihood value of the likelihood information and a predetermined threshold, accumulates the detected error count, and estimates the error symbol count after decoding.

5. The decoder according to claim 1, wherein the iterative decoding control circuit judges whether the estimated error symbol count exceeds an error symbol count that can be corrected by the ECC decoder, and decides to continue the iterative decoding when it is judged that the estimated error symbol count exceeds the error symbol count that can be corrected by the ECC decoder.

6. The decoder according to claim 1, wherein the iterative decoding control circuit comprises:
a buffer which stores the likelihood information of the decoder;
an error decision circuit which estimates the error symbol count after decoding using the likelihood information of the buffer, and decides whether decoding is continued by a decoder in the next step of the iterative decoder based on the estimated error symbol count and an error symbol count that can be corrected by the ECC decoder;
a binary circuit which binarizes the likelihood information in the buffer;
a first gate circuit which outputs the likelihood information in the buffer to the decoder in the next step of the iterative decoder when the error decision circuit decides to continue decoding; and
a second gate circuit which outputs the likelihood information in the buffer to the binary circuit when the error decision circuit decides to continue decoding.

7. The decoder according to claim 2, wherein the iterative decoding control circuit compares the estimated error symbol count of each block and the error symbol count that can be corrected by the ECC decoder, calculates a block count that cannot be corrected, and decides whether decoding by the decoder in the next step of the iterative decoder is continued based on the block count that cannot be corrected.

8. The decoder according to claim 7, wherein the iterative decoding control circuit judges whether the estimated error symbol count in each block exceeds the error symbol count that can be corrected by the ECC decoder, and if exceeded, the iterative decoding control circuit judges the block as a block that cannot be corrected.

9. The decoder according to claim 1, wherein the outer code decoder comprises a low density parity decoder.

10. A recording/reproducing device for reading and decoding a signal which is added an ECC code and an outer code to a predetermined number of bits of data, from a storage medium, comprising:
an iterative decoder to which the signal is input, and comprises a plurality of decoder which is each constituted by a soft input soft output detector and an outer code decoder and is constructed in multiple steps;
an ECC decoder which corrects a binary output of the iterative decoder using an ECC code; and
an iterative decoding control circuit which estimates an error symbol count after decoding using likelihood information of the decoder and decides whether decoding is continued using a decoder in the next step of the iterative decoder based on the estimated error symbol count and an error symbol count which can be corrected by the ECC decoder,
wherein when it is decided to continue the decoding, the iterative decoding control circuit outputs the likelihood information of a target decoder of the decision to a decoder in the next step and performs iterative decoding, and when it is decided not to continue the decoding, the iterative decoding control circuit outputs binary output of the likelihood information of the target decoder of the decision to the ECC decoder.

11. The recording/reproducing device according to claim 10, wherein the signal is a signal resulting after the data is interleaved, the ECC code is added to each interleaved data block, and de-interleave is then performed,
and the iterative decoding control circuit interleaves the likelihood information of the decoder, estimates the error symbol count after decoding of each block using each likelihood information of the interleaved block, and decides whether decoding is continued using a decoder in the next step of the iterative decoder based on the estimated error symbol count of each block and error symbol count that can be corrected by the ECC decoder.

12. The recording/reproducing device according to claim 10, wherein the iterative decoding control circuit estimates the error symbol count after decoding based on the likelihood information of the data and ECC code.

13. The recording/reproducing device according to claim 10, wherein the iterative decoding control circuit detects the error by comparing a likelihood value of the likelihood information and a predetermined threshold, accumulates the detected error count, and estimates the error symbol count after decoding.

14. The recording/reproducing device according to claim 10, wherein the iterative decoding control circuit judges whether the estimated error symbol count exceeds an error symbol count that can be corrected by the ECC decoder, and decides to continue the iterative decoding when it is judged that the estimated error symbol count exceeds the error symbol count that can be corrected by the ECC decoder.

15. The recording/reproducing device according to claim 10, wherein the iterative decoding control circuit comprises:
a buffer which stores the likelihood information of the decoder;
an error decision circuit which estimates the error symbol count after decoding using the likelihood information of the buffer, and decides whether decoding is continued by a decoder in the next step of the iterative decoder based on the estimated error symbol count and an error symbol count that can be corrected by the ECC decoder;
a binary circuit which binarizes the likelihood information in the buffer;
a first gate circuit which outputs the likelihood information in the buffer to the decoder in the next step of the iterative decoder when the error decision circuit decides to continue decoding; and
a second gate circuit which outputs the likelihood information in the buffer to the binary circuit when the error decision circuit decides to continue decoding.

16. The recording/reproducing device according to claim 11, wherein the iterative decoding control circuit compares the estimated error symbol count of each block and the error symbol count that can be corrected by the ECC decoder, calculates a block count that cannot be corrected, and decides whether decoding by the decoder in the next step of the iterative decoder is continued based on the block count that cannot be corrected.

17. The recording/reproducing device according to claim 16, wherein the iterative decoding control circuit judges whether the estimated error symbol count in each block exceeds the error symbol count that can be corrected by the ECC decoder, and if exceeded, the iterative decoding control circuit judges the block as a block that cannot be corrected.

18. The recording/reproducing device according to claim 10, wherein the outer code decoder comprises a low density parity decoder.
